(19) United States
(12) Patent Application Publication
(10) Pub. No.: US 2017/0227607 A1
(43) Pub. Date: Aug. 10, 2017

(54) SCHEMES CAPABLE OF EFFICIENTLY AND ACCURATELY ESTIMATING AND/OR PREDICTING AVAILABLE BATTERY CAPACITY AND BATTERY AGING FACTOR

(71) Applicant: MEDIATEK INC., Hsin-Chu (TW)

(72) Inventors: Jui-Chi Wu, Taichung City (TW); Jia-You Chuang, Hsinchu County (TW); Wan-Yi Horng, Hsinchu City (TW); Jui Wang, Taichung City (TW)

(21) Appl. No.: 15/285,497

(22) Filed: Oct. 5, 2016

Related U.S. Application Data
(60) Provisional application No. 62/291,474, filed on Feb. 4, 2016.

(51) Int. Cl. G01R 31/36; H01M 6/50; H01M 10/42

(52) U.S. Cl. CPC G01R 31/3634; H01M 10/4285; H01M 6/5083; G01R 31/3679; G01R 31/3651; G01R 31/3662

(57) ABSTRACT

Methods are provided to be able to efficiently and precisely estimate/predict an available capacity of a battery. One method is arranged to estimate/predict the available capacity of the battery according to a first battery percentage result, a second battery percentage result, and a calculated power when the battery is being operated or used within a specific operating range distinct from a normal operating range. Another method is arranged to estimate the available capacity by measuring battery's internal resistance and referencing a precise battery aging model.

### CROSS REFERENCE TO RELATED APPLICATIONS

This application claims priority of U.S. provisional application Ser. No. 62/291,474 filed on Feb. 4, 2016, which is entirely incorporated herein by reference.

### BACKGROUND

Generally speaking, a battery device may be aged after being cycled many times, and the total capacity of the battery (i.e. the battery's available capacity) will be decreased and become different from the battery's rated capacity. This inevitably causes errors if a battery power estimation/prediction procedure is based on the battery's rated capacity while the battery has been aged. Some conventional schemes have been provided to estimate the available capacity of the battery but the conventional schemes still cannot estimate the available capacity efficiently and accurately.

### SUMMARY

Therefore one of the objectives of the invention is to provide schemes capable of more efficiently and accurately estimating and/or predicting an available battery capacity and battery aging factor, to solve the above-mentioned problems.

According to embodiments of the invention, a method for estimating an available capacity of a battery is disclosed. The method comprising: determining whether a battery is within a specific operating range being distinct from a normal operating range of the battery; generating a first battery percentage result of the battery when the battery is within the specific operating range, the first battery percentage result being defined by one of depth-of-discharge and state-of-charge; calculating a power provided by or charged for the battery between the first battery percentage result and a second battery percentage result; and, estimating the available capacity of the battery according to the first battery percentage result, the second battery percentage result, and the calculated power.

According to the embodiments of the invention, a method for estimating an available capacity of a battery is disclosed. The method comprises: measuring an internal resistance of the battery to generate a measured resistance; and, estimating the available capacity of the battery by referencing the measured resistance and a second look-up table defining a relation between the internal resistance of the battery and the available capacity of the battery.

According to the embodiments, a power management apparatus capable of estimating/predicting an available capacity of a battery is disclosed. The power management apparatus comprises a storage circuit and a controlling circuit. The controlling circuit is coupled to the storage circuit and arranged for loading program codes from the storage circuit to execute steps of: determining whether a battery is within a specific operating range being distinct from a normal operating range of the battery; generating a first battery percentage result of the battery when the battery is within the specific operating range, the first battery percentage result being defined by one of depth-of-discharge and state-of-charge; calculating a power provided by or charged for the battery between the first battery percentage result and a second battery percentage result; and, estimating the available capacity of the battery according to the first battery percentage result, the second battery percentage result, and the calculated power.

According to the embodiments, a power management apparatus capable of estimating/predicting an available capacity of a battery is disclosed. The power management apparatus comprises a storage circuit and a controlling circuit. The controlling circuit is coupled to the storage circuit and arranged for loading program codes from the storage circuit to execute steps of: measuring an internal resistance of the battery to generate a measured resistance; and estimating the available capacity of the battery by referencing the measured resistance and a second look-up table defining a relation between the internal resistance of the battery and the available capacity of the battery.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conceptual flowchart of a method for estimating and/or predicting an available capacity of a battery according to a set of embodiments of the invention.

FIG. 2 is a diagram illustrating a flowchart of a method for estimating and/or predicting the available capacity of the battery according to an embodiment of FIG. 1.

FIG. 3 is a diagram illustrating a flowchart of a method for estimating and/or predicting the available capacity of the battery according to another embodiment of FIG. 1.

FIG. 4 is a diagram illustrating a flowchart of a method for estimating and/or predicting the available capacity of the battery according to another embodiment of FIG. 1.

FIG. 5 is a block diagram of a power management circuit according to the embodiments of FIGS. 1-4 and/or the embodiments of FIGS. 7-8.

FIG. 6 is a diagram illustrating an example of the first look-up table defining the relation between the battery cell voltage and the available capacity of the battery.

FIG. 7 is a diagram showing a flowchart of the method for converting the first look-up table to generate the second look-up table so as to generate/form the precise battery aging model according to an embodiment of the present invention.

FIG. 8 is a diagram showing a flowchart of the method for predicting the available capacity of the battery based on the precise battery aging model according to an embodiment of the present invention.

### DETAILED DESCRIPTION

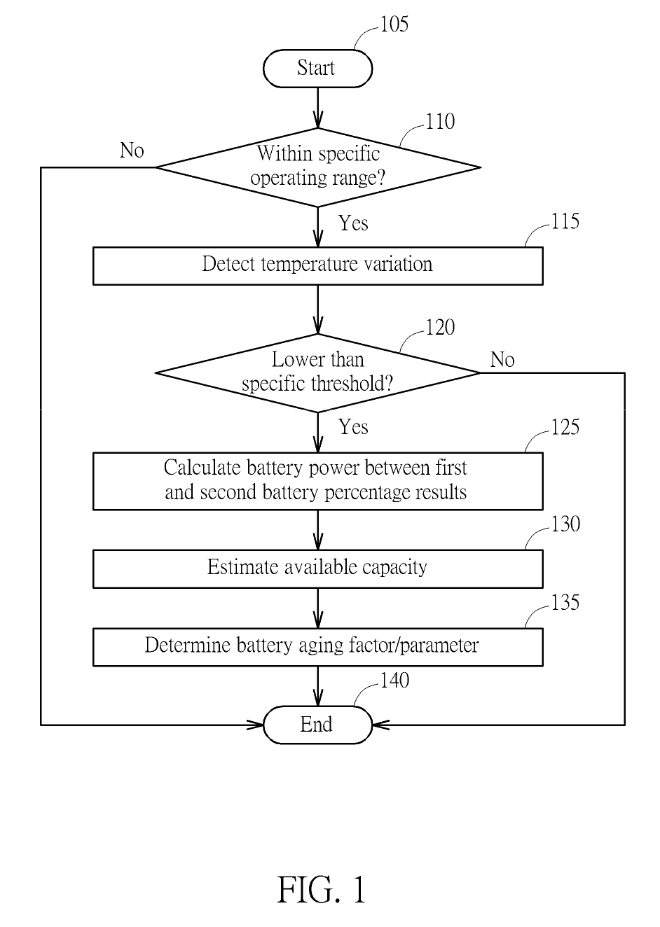

Please refer to FIG. 1, which is a diagram illustrating a conceptual flowchart of a method for estimating and/or predicting an available capacity of a battery according to a set of embodiments of the invention. More particularly, the method can be used for effectively and correctly estimating the available capacity of the battery even though the battery has been aged or cycled many times. Provided that substantially the same result is achieved, the steps of the flowchart shown in FIG. 1 need not be in the exact order shown and need not be contiguous, that is, other steps can be intermediate. Steps of FIG. 1 are detailed in the following:

Step 105: Start;

Step 110: determining whether a battery is being used or operated within a specific operating range being distinct from a normal operating range of the battery; if so, the flow proceeds to Step 115; otherwise, the flow proceeds to Step 140;

Step 115: detecting a temperature variation of the battery;

Step 120: determining whether the temperature variation of the battery is lower than a specific threshold; if so, the flow proceeds to Step 125, otherwise, the flow proceeds to Step 140;

Step 125: calculating a power provided by or charged for the battery between a first battery percentage result (defined by the depth-of-discharge (DOD) or defined by state-of-charge (SOC), i.e. battery power percentage) and a second battery percentage result of the battery wherein the first battery percentage result is configured to correspond to the specific operating range outside the normal operating range, and the second battery percentage result is a specific percent of depth-of-discharge which is one selected from 100% depth-of-discharge and 0% depth-of-discharge;

Step 130: estimating the available capacity of the battery according to the calculated power, the first battery percentage result, and the second battery percentage result;

Step 135: determining a battery aging factor/parameter according to the estimated available capacity and an ideal capacity of the battery; and

Step 140: End.

In Step 110, the method for estimating the available capacity is trigged and performed when the battery is being used within the specific operating range outside the normal operating range. The normal operating range means an operating range defined by a battery voltage range in which the slope of relation between the battery cell voltage and battery's depth-of-discharge (or state-of-charge) is more flat while the specific operating range means an operating range outside the normal operating range and can be defined by a battery voltage range in which the slope of relation between the battery cell voltage and battery's depth-of-discharge (or state-of-charge) is sharper and thus estimation of available capacity based on the specific operating range can be more accurate and efficient. That is, a slope of voltage changes within the specific operating range is greater than a slope of voltage changes within the normal operating range of the battery. In an embodiment, the normal operating range is defined by a normal operating voltage range of the battery, and the specific operating range is defined by a voltage range outside the normal operating voltage range. In another embodiment, the normal operating range is defined by a battery power percentage range of the battery, and the specific operating range is defined by a battery percentage range outside the battery power percentage range of the battery. In another embodiment, the battery power percentage range of the battery can be configured based on the normal operating voltage range of the battery. For example, the battery power percentage range of the battery can be defined and configured based on the normal operating voltage range. For instance, the battery power percentage range can be configured a power percentage range from 30% state-of-charge to 70% state-of-charge, i.e. a power discharge range from 70% depth-of-discharge (DOD) of the battery to 30% depth-of-discharge of the battery. The specific operating range can be defined by a voltage range comprising a first voltage range corresponding to a power discharge range from 70% depth-of-discharge to 100% depth-of-discharge and/or a second voltage range corresponding to a power discharge range from 30% depth-of-discharge to 0% depth-of-discharge. The first voltage range and the second voltage range are isolated by the normal operating voltage range. It should be noted that the definition of the normal operating range of the battery is not meant to be a limitation of the invention. In other embodiments, the normal operating voltage range can be defined by different ranges such as an operating voltage range corresponding to a power discharge range from 20% depth-of-discharge (DOD) of the battery to 80% depth-of-discharge of the battery, and the specific operating range is adjusted correspondingly.

A larger temperature variation of the battery may cause an inaccuracy estimation of available capacity of the battery, and Step 115 and Step 120 are used and performed to keep the estimation more accurate; however, Step 115 and Step 120 are optional and can be omitted in other embodiments.

In Step 125, the method is arranged to adopt a coulomb counter to calculate power totally provided by the battery when the battery is discharged from 0% depth-of-discharge to the first battery power percentage such as 30% state-of-charge (i.e. 70% depth-of-discharge), or to adopt the coulomb counter to calculate power totally charged for the battery when the battery is charged from 100% depth-of-discharge to the first battery power percentage such as 70 state-of-charge (i.e. 30% depth-of-discharge).

In Step 130, the method is arranged to estimate the available capacity of the battery according to the calculated power, the first battery percentage result, and the second battery percentage result directly. In another embodiment, the method can be arranged to convert the first battery percentage result and the second battery percentage result to a first battery cell voltage and a second battery cell voltage correspondingly by referring a look-up table which defines a relation between levels of open circuit voltage of the battery (i.e. the battery cell voltage) and values of the available capacity of the battery. Then, the method is arranged to estimate the available capacity of the battery based on the calculated power, the first battery cell voltage, and the second battery cell voltage directly. The advantage of estimating the available capacity of the battery based on the calculated power, the first battery cell voltage, and the second battery cell voltage directly is that the range of changes of corresponding battery cell voltages can be boarder than that of changes of the above-mentioned percentages. In addition, it is easy to obtain the corresponding battery cell voltages by converting the above-mentioned percentages to generate the corresponding battery cell voltages based on the look-up table.

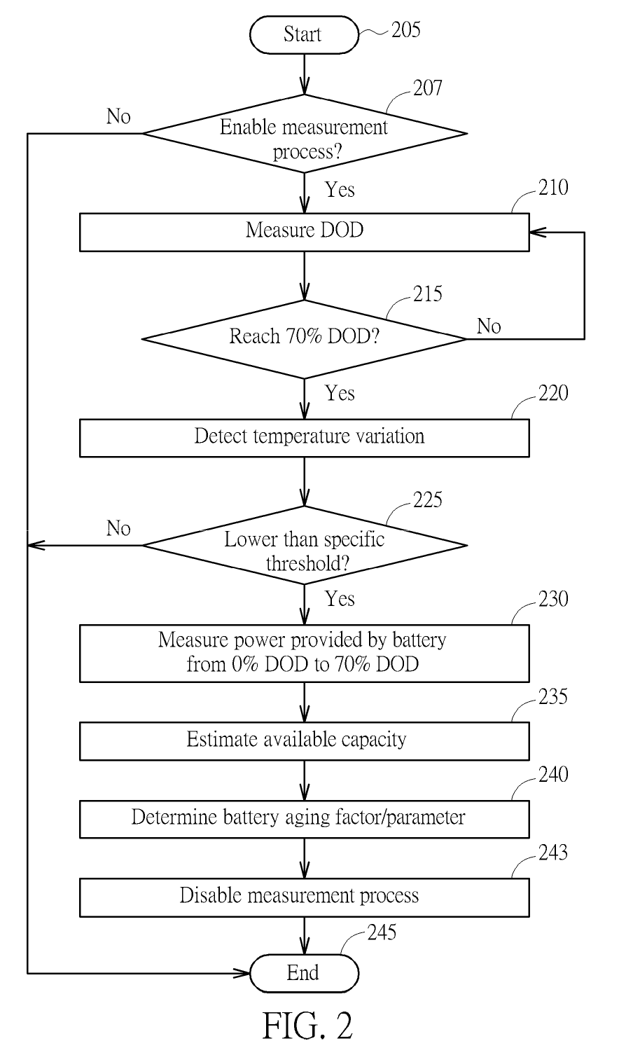

In an embodiment of FIG. 1, the method for estimating the available capacity of the battery is performed by calculating/measuring power totally provided by the battery from 100% state-of-charge (i.e. 0% depth-of-discharge) of the battery to 30% state-of-charge (i.e. 70% depth-of-discharge) of the battery. FIG. 2 shows a flowchart according to the embodiment. Steps of FIG. 2 are detailed in the following:

Step 205: Start;

Step 207: determining whether the measurement process of the available capacity of the battery has been enabled? If so, the flow proceeds to Step 210; otherwise, the flow proceeds to Step 245;

Step 210: measuring the depth-of-discharge of the battery up to now;

Step 215: determining whether the measured depth-of-discharge of the battery reaches a percent depth-of-discharge corresponding to the first battery power percentage (such as 70% depth-of-discharge corresponding to 30% state-of-charge) or becomes greater than 70% depth-of-discharge? If so, the flow proceeds to Step 220; otherwise, the flow proceeds to Step 210 to measure the depth-of-discharge of the battery again;

Step 220: detecting a temperature variation of the battery;

Step 225: determining whether the detected temperature variation of the battery is lower than the specific threshold such as 10 degrees centigrade? If so, the flow proceeds to Step 230, otherwise, the flow proceeds to Step 245;

Step 230: adopting a coulomb counter to measure power totally provided by the battery from 100% state-of-charge to first battery power percentage such as 30% state-of-charge (i.e. from 0% depth-of-discharge to 70% depth-of-discharge);

Step 235: calculating and estimating the available capacity of the battery according to the measured power and the first battery power percentage;

Step 240: determining a battery aging factor/parameter according to the estimated available capacity and an ideal capacity of the battery;

Step 243: Disabling the measurement process of the available capacity of the battery; and

Step 245: End.

In Step 210, measuring the depth-of-discharge of the battery up to now can be implemented by making the battery enter a sleep mode, detecting a battery cell voltage of the battery at this moment, and then looking up a specific table to find the depth-of-discharge of the battery. A voltage ADC can be employed to measure the battery cell voltage of the battery.

In Step 215, the normal operating range is defined by a power discharge range from 0% depth-of-discharge to 70% depth-of-discharge, and the specific operating range mentioned above can be configured to be outside the normal operating range, e.g. a power discharge range from 70% depth-of-discharge to 100% depth-of-discharge. Once the measured depth-of-discharge of the battery becomes higher than 70% depth-of-discharge, the method for estimating the available capacity of the battery is triggered and performed.

The larger temperature variation of the battery may cause an inaccuracy estimation of available capacity of the battery, and Step 220 and Step 225 are used and performed to keep the estimation more accurate; however, Step 220 and Step 225 are optional and can be omitted in other embodiments.

In Step 230, when the battery reaches 0% depth-of-discharge (or 100% state-of-charge), the result of 0% depth-of-discharge can be reported by a charger circuit. It is not required to make the battery enter the sleep mode and detect the battery cell voltage to know when the battery reaches 0% depth-of-discharge. That is, for the method of FIG. 2, it is only required to make the battery enter the sleep mode one time to detect the battery cell voltage, instead of making the battery enter the sleep mode two times. The sleep mode means that the battery provides a smaller current due to a light loading condition or provides no currents since of a no-loading condition.

In Step 235, the available capacity of the battery is estimated and calculated based on the following equation:

$$Qmax\_est = \frac{CAR}{FG\_DOD} \times 100$$

wherein Qmax_est represents the estimated available capacity of the battery, CAR represents the total power measured by the coulomb counter, and FG_DOD means the currently measured percent depth-of-discharge of the battery in Step 210. In addition, in Step 240, the battery aging factor/parameter is determined based on the following equation:

$$AF = \frac{Qmax\_est}{Q max}$$

wherein AF means the battery aging factor/parameter, and Qmax means the ideal capacity of the battery.

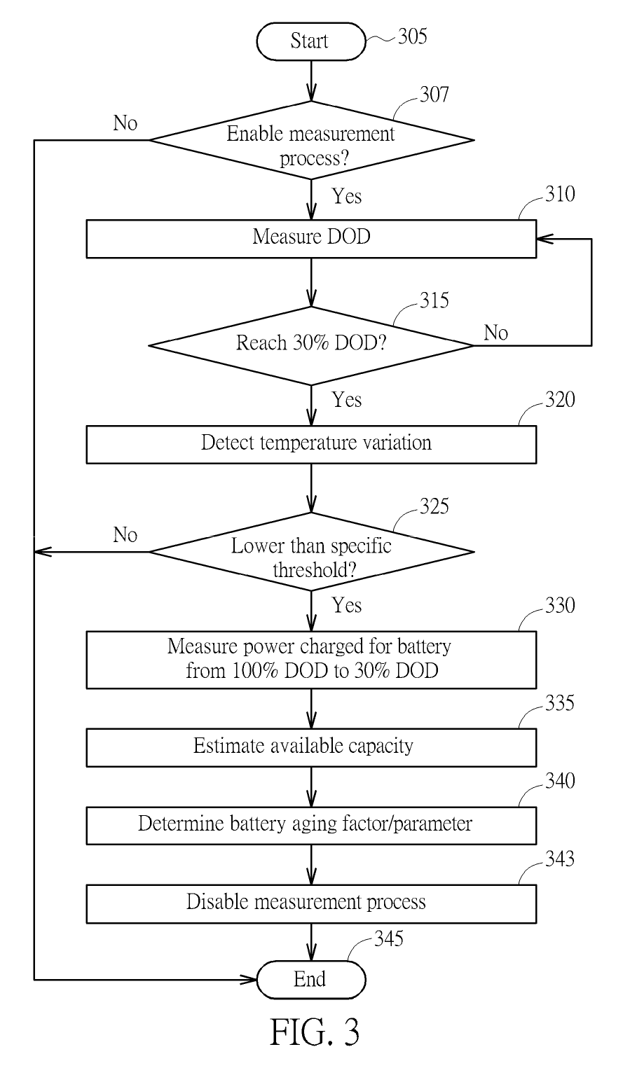

In another embodiment of FIG. 1, the method for estimating the available capacity of the battery is performed by calculating/measuring power totally charged for the battery from 0% state-of-charge (i.e. 100% depth-of-discharge) of the battery to 70% state-of-charge (i.e. 30% depth-of-discharge) of the battery. FIG. 3 shows a flowchart according to the embodiment. Steps of FIG. 3 are detailed in the following:

Step 305: Start;

Step 307: determining whether the measurement process of the available capacity of the battery has been enabled? If so, the flow proceeds to Step 310; otherwise, the flow proceeds to Step 345;

Step 310: measuring the depth-of-discharge of the battery up to now;

Step 315: determining whether the depth-of-discharge of the battery reaches the first battery power percentage (such as 30% depth-of-discharge) or becomes lower than 30% depth-of-discharge? If so, the flow proceeds to Step 320, otherwise, the flow proceeds to Step 310 to measure the depth-of-discharge of the battery again;

Step 320: detecting a temperature variation of the battery;

Step 325: determining whether the detected temperature variation of the battery is lower than the specific threshold such as 10 degrees centigrade? If so, the flow proceeds to Step 330, otherwise, the flow proceeds to Step 345;

Step 330: adopting a coulomb counter to measure power totally charged for the battery from 0% state-of-charge to first battery power percentage such as 70% state-of-charge (i.e. from 100% depth-of-discharge to 30% depth-of-discharge);

Step 335: calculating and estimating the available capacity of the battery according to the measured power and the first battery power percentage;

Step 340: determining the battery aging factor/parameter according to the estimated available capacity and an ideal capacity of the battery;

Step 343: Disabling the measurement process of the available capacity of the battery; and

Step 345: End.

In Step 330, when the battery reaches 100% depth-of-discharge (or 0% state-of-charge), the result of 100% depth-of-discharge can be reported by a charger circuit. It is not required to make the battery enter the sleep mode and detect the battery cell voltage to know when the battery reaches 100% depth-of-discharge. That is, for the method of FIG. 3, it is only required to make the battery enter the sleep mode one time to detect the battery cell voltage, instead of making the battery enter the sleep mode two times.

In Step 335, the available capacity of the battery is estimated and calculated based on the following equation:

$$Qmax\_est = \frac{CAR}{100 - FG\_DOD} \times 100$$

wherein Qmax_est represents the estimated available capacity of the battery, CAR represents the total power measured by the coulomb counter, and FG_DOD means the measured percent depth-of-discharge of the battery. In addition, in Step 340, the battery aging factor/parameter is determined based on the following equation:

$$AF = \frac{Qmax\_est}{Q max}$$

wherein AF means the battery aging factor/parameter, and Qmax means the ideal capacity of the battery.

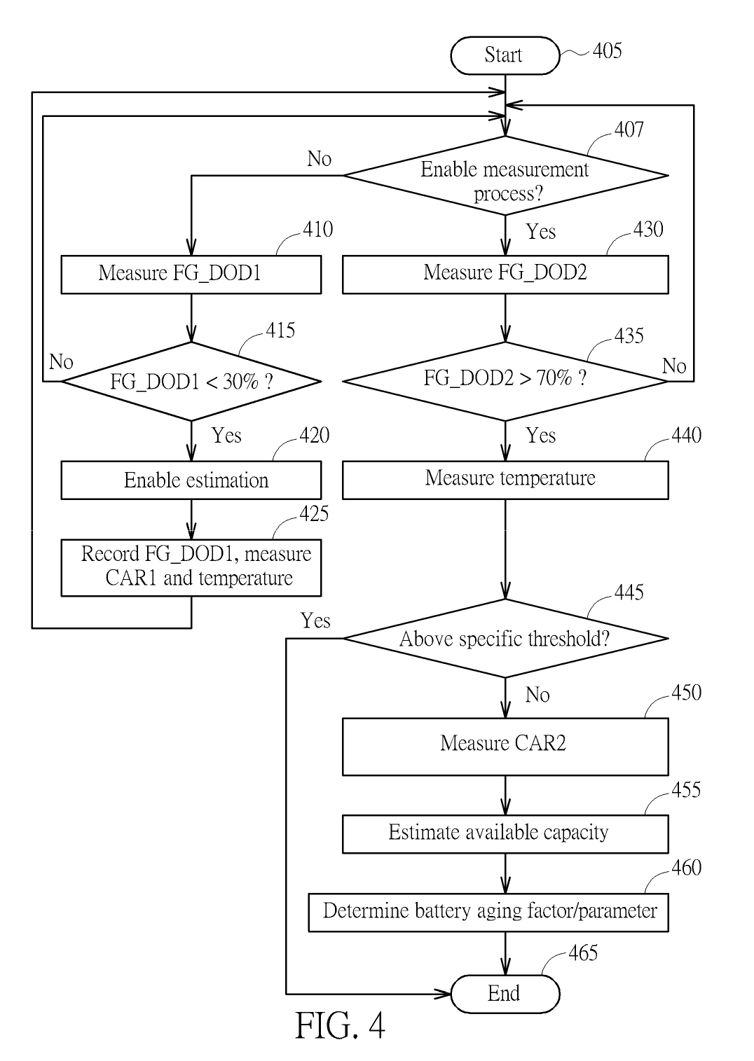

In another embodiment of FIG. 1, the method for estimating the available capacity of the battery is performed by calculating/measuring power totally provided by the battery from 70% state-of-charge (i.e. 30% depth-of-discharge) of the battery to 30% state-of-charge (i.e. 70% depth-of-discharge) of the battery or power totally charged for the battery from 30% state-of-charge (i.e. 70% depth-of-discharge) of the battery to 70% state-of-charge (i.e. 30% depth-of-discharge) of the battery. FIG. 4 shows a flowchart of measuring the power totally provided by the battery according to the embodiment. Steps of FIG. 4 are detailed in the following:

Step 405: Start;

Step 407: determining whether the measurement process of the available capacity of the battery has been enabled? If so, the flow proceeds to Step 430; otherwise, the flow proceeds to Step 410;

Step 410: measuring the current percent depth-of-discharge FG_DOD1 of the battery up to now;

Step 415: determining whether the measured depth-of-discharge FG_DOD1 of the battery is below the first percent depth-of-discharge such as 30% (i.e. 70% state-of-charge)? If so, the flow proceeds to Step 420, otherwise, the flow proceeds to Step 407;

Step 420: initializing/enabling the method (the measurement process) for estimating the available capacity of the battery;

Step 425: recording the current percent depth-of-discharge FG_DOD1 of the battery, measuring the power CAR1 provided by the battery from 0% depth of discharge to the current percent depth of discharge, and measuring and recording the temperature of the battery;

Step 430: measuring the current percent depth-of-discharge FG_DOD2 of the battery again;

Step 435: determining whether the current percent depth-of-discharge FG_DOD2 of the battery is above the second percent depth of discharge such as 70% (i.e. 30% state of charge)? If so, the flow proceeds to Step 440, otherwise, the flow proceeds to Step 407;

Step 440: measuring and recording the temperature of the battery again;

Step 445: determining whether the temperature variation of the battery is above the specific threshold such as 10 degrees centigrade? If so, the flow proceeds to Step 465, otherwise, the flow proceeds to Step 450;

Step 450: measuring and calculating the power CAR2 totally provided by the battery from 0% depth-of-discharge to the percent depth-of-discharge FG_DOD2;

Step 455: estimating the available capacity of the battery according to the totally provided power and the difference between the percent depth-of-discharge measurements;

Step 460: determining the battery aging factor/parameter according to the estimated available capacity and an ideal capacity of the battery; and

Step 465: End.

In Step 455, the available capacity of the battery is estimated and calculated based on the following equation:

$$Qmax\_est = \frac{CAR 2 - CAR 1}{FG\_DOD 2 - FG\_DOD 1}$$

wherein Qmax_est represents the estimated available capacity of the battery, CAR2 represents the battery's power measured by the coulomb counter at the second time, CAR1 represents the battery's power measured by the coulomb counter at the first time, FG_DOD1 represents the percent depth-of-discharge of the battery measured at the first time, and FG_DOD2 represents the percent depth-of-discharge of the battery measured at the second time. In addition, in Step 460, the battery aging factor/parameter is determined based on the following equation:

$$AF = \frac{Qmax\_est}{Q max}$$

wherein AF means the battery aging factor/parameter, and Qmax means the ideal capacity of the battery.

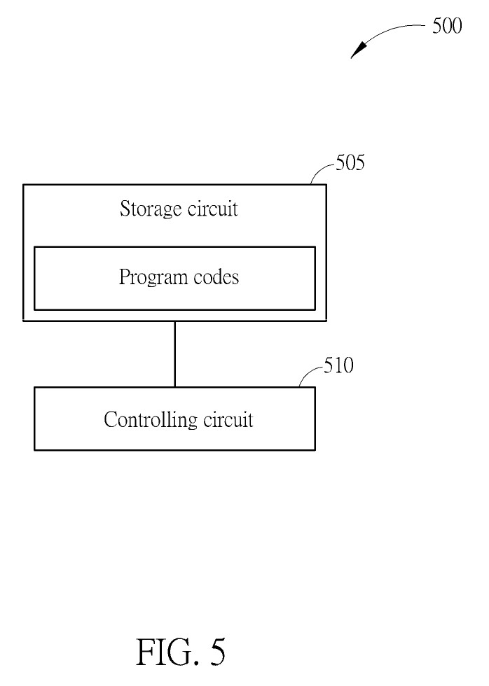

FIG. 5 is a block diagram of a power management apparatus 500 according to embodiments of FIGS. 1-4. The power management apparatus 500 is capable of estimating/predicting the available capacity of the battery and comprises a storage circuit 505 and a controlling circuit 510. The controlling circuit 510 is arranged to load program codes from the storage circuit 505 such as a register circuit and can respectively execute the steps as shown in FIGS. 1-4 to estimate the available capacity of the battery 501 coupled to the power management circuit 500. The normal operating range and specific operating range can be configured by the controlling circuit 510 in advance. In addition, the controlling circuit 510 can be arranged to adjust the specific operating range step by step in response to different temperate conditions.

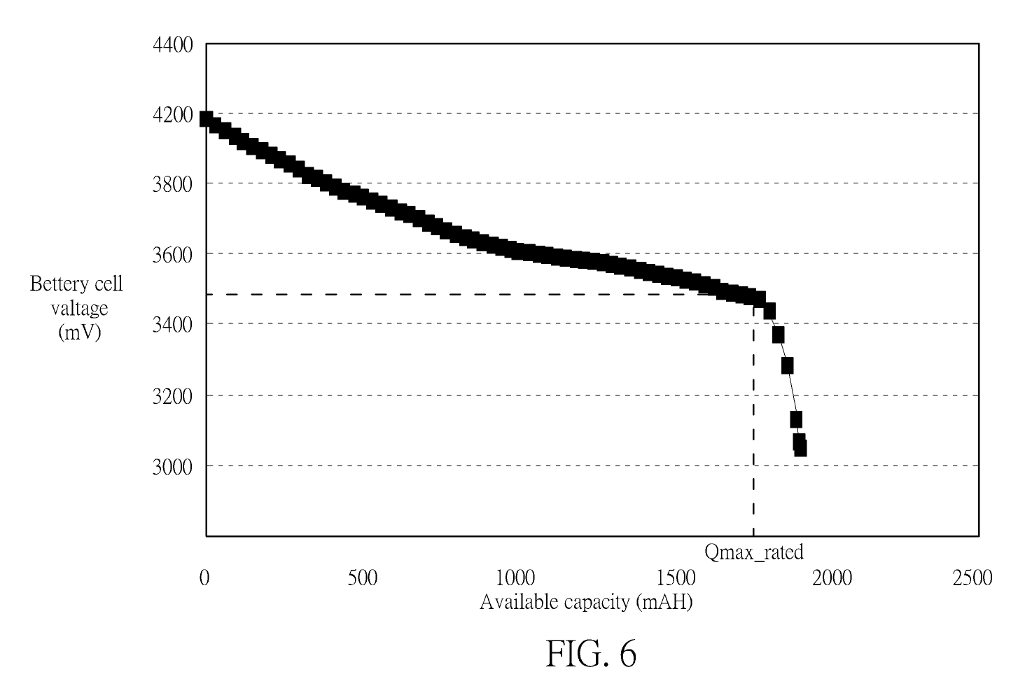

Furthermore, in other embodiments, the controlling circuit 510 can be arranged to establish a precise battery aging model to predict/estimate the available capacity of the battery. The precise battery aging model can be stored in the storage circuit 505. The precise battery aging model is equivalently regarded as a second look-up table defining a relation between values of internal resistance of the battery and values of the available capacity of the battery. The controlling circuit 510 can convert a first look-up table to generate/establish the second look-up table wherein the first look-up table defines a relation between levels of open circuit voltage of the battery (i.e. the battery cell voltage) and values of the available capacity of the battery. The information/content of first look-up table can be generated and stored in the storage circuit 505 when the battery is in the factory. FIG. 6 is a diagram illustrating an example of the first look-up table mentioned above. As shown in FIG. 6, the curve as shown in FIG. 6 represents information and content of the first look-up table. Qmax_rated means the rated capacity of battery (i.e. the ideal capacity) and indicates a corresponding battery cell voltage. Once the battery becomes aged gradually, the value of available capacity of the battery is gradually decreased, and the corresponding level of battery cell voltage becomes higher gradually. The curve of FIG. 6 is generated or formed based on the temperature of 25 degrees centigrade; however, this is not meant to be a limitation of the present invention. Examples of the curve defined by content/information of the first look-up table may be different when the battery is operated or used under different temperature conditions.

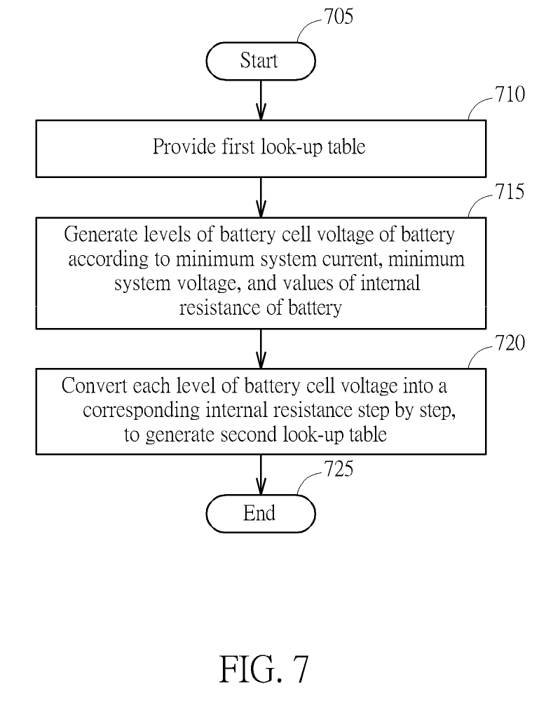

FIG. 7 is a diagram showing a flowchart of the method for converting the first look-up table to generate the second look-up table so as to generate/form the precise battery aging model according to an embodiment of the present invention. Provided that substantially the same result is achieved, the steps of the flowchart shown in FIG. 7 need not be in the exact order shown and need not be contiguous, that is, other steps can be intermediate. Steps of FIG. 7 are detailed in the following:

Step 705: Start;

Step 710: providing the first look-up table defining the relation between levels of the battery cell voltage of the battery and values of the available capacity of the battery;

Step 715: generating corresponding levels of the battery cell voltage of the battery according to a minimum system current, a minimum system voltage, and values of the internal resistance of the battery;

Step 720: based on the first look-up table, converting each level of the battery cell voltage of the battery into a corresponding internal resistance of the battery step by step, to generate the second look-up table (i.e. battery aging model); and

Step 725: End.

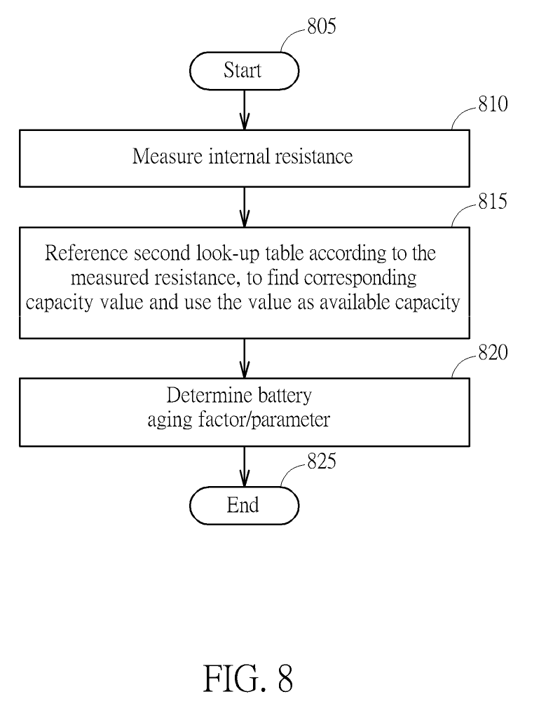

After the first look-up table has been converted to generate the second look-up table, the controlling circuit 510 can accurately predict/estimate the available capacity of the battery by measuring the internal resistance of the battery to generate a measured resistance and then referencing information of the second look-up table based on the measured resistance and a battery rated capacity (i.e. the ideal value of total battery capacity). This can provide the benefit of estimating/predicting the available capacity more efficiently and accurately. FIG. 8 is a diagram showing a flowchart of the method for predicting the available capacity of the battery based on the precise battery aging model according to an embodiment of the present invention. Provided that substantially the same result is achieved, the steps of the flowchart shown in FIG. 8 need not be in the exact order shown and need not be contiguous, that is, other steps can be intermediate. Steps of FIG. 8 are detailed in the following:

Step 805: Start;

Step 810: measuring the internal resistance of the battery to generate the measure resistance;

Step 815: referencing the second look-up table according to the measured resistance, to find or obtain a corresponding capacity value and use the value as the available capacity of the battery;

Step 820: determining the battery aging factor/parameter according to the estimated available capacity and the battery rated capacity; and

Step 825: End.

The minimum system current and the minimum system voltage are used to find which operating threshold point the system can work and consumes little current and voltage. The system will be shut down when the system is below the operating threshold point. However, this is not meant to be a limitation of the invention. Different system current and voltage may be useful for estimating/predicting the available capacity of the battery. In addition, steps of FIGS. 7-8 can coexist and can be executed by the controlling circuit 510 at different timings or under different user's usage conditions. Steps of FIGS. 7-8 and steps of FIGS. 1-4 can be executed by respective different circuits.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for estimating an available capacity of a battery, comprising:
determining whether a battery is within a specific operating range being distinct from a normal operating range of the battery;
generating a first battery percentage result of the battery when the battery is within the specific operating range, the first battery percentage result being defined by one of depth-of-discharge and state-of-charge;
calculating a power provided by or charged for the battery between the first battery percentage result and a second battery percentage result; and
estimating the available capacity of the battery according to the first battery percentage result, the second battery percentage result, and the calculated power.

2. The method of claim 1, wherein the second battery percentage result is one of 0% depth-of-discharge and 100% depth-of-discharge.

3. The method of claim 1, wherein the specific operating rage is defined by a specific battery percentage range that is defined by one of state-of-charge and depth-of-discharge.

4. The method of claim 1, wherein the specific operating rage is defined by a specific operating voltage range distinct from a normal operating voltage range of the battery.

5. The method of claim 1, further comprising:
determining whether the battery reaches a second part of the specific operating range; and
generating the second battery percentage result of the battery when the battery is within the second part of the specific operating range;
wherein the first battery power percentage is generated in response to that when the battery is within a first part of the specific operating range, the first part of the specific operating range and the second part of the specific operating range are separated by the normal operating range of the battery.

6. The method of claim 1, further comprising:
detecting a temperature variation of the battery between the first battery percentage result and the second battery percentage result;
wherein the step of estimating the available capacity of the battery is executed only when the detected temperature variation between the first battery percentage result and the second battery percentage result is lower than a specific threshold.

7. The method of claim 1, further comprising:
determining a battery aging factor according to the estimated available capacity and an ideal capacity of the battery.

8. The method of claim 1, wherein a slope of voltage changes within the specific operating range is greater than a slope of voltage changes within the normal operating range of the battery.

9. A method for estimating an available capacity of a battery, comprising:
measuring an internal resistance of the battery to generate a measured resistance; and
estimating the available capacity of the battery by referencing the measured resistance and a second look-up table defining a relation between the internal resistance of the battery and the available capacity of the battery.

10. The method of claim 9, further comprising:
providing a first look-up table defining a relation between a battery cell voltage of the battery and the available capacity of the battery;
calculating levels of the battery cell voltage of the battery based on a minimum system current provided from the battery, a minimum system voltage, and values of the internal resistance; and
converting the first look-up table into the second look-up table by mapping the levels of the battery cell voltage of the battery to the values of the internal resistance of the battery.

11. The method of claim 9, further comprising:
determining an aging factor according to the measured resistance and an ideal value of the internal resistance of the battery.

12. A power management apparatus capable of estimating/predicting an available capacity of a battery, comprising:
a storage circuit; and
a controlling circuit, coupled to the storage circuit, for loading program codes from the storage circuit to execute steps of:
determining whether a battery is within a specific operating range being distinct from a normal operating range of the battery;
generating a first battery percentage result of the battery when the battery is within the specific operating range, the first battery percentage result being defined by one of depth-of-discharge and state-of-charge;
calculating a power provided by or charged for the battery between the first battery percentage result and a second battery percentage result; and
estimating the available capacity of the battery according to the first battery percentage result, the second battery percentage result, and the calculated power.

13. The power management apparatus of claim 12, wherein the second battery percentage result is one of 0% depth-of-discharge and 100% depth-of-discharge.

14. The power management apparatus of claim 12, wherein the specific operating rage is defined by a specific battery percentage range that is defined by one of state-of-charge and depth-of-discharge.

15. The power management apparatus of claim 12, wherein the specific operating rage is defined by a specific operating voltage range distinct from a normal operating voltage range of the battery.

16. The power management apparatus of claim 12, wherein the controlling circuit is further arranged to:
determine whether the battery reaches a second part of the specific operating range; and
generate the second battery percentage result of the battery when the battery is within the second part of the specific operating range;
wherein the first battery power percentage is generated in response to that when the battery is within a first part of the specific operating range, the first part of the specific operating range and the second part of the specific operating range are separated by the normal operating range of the battery.

17. The power management apparatus of claim 12, wherein the controlling circuit is further arranged to:
detecting a temperature variation of the battery between the first battery percentage result and the second battery percentage result;
wherein the controlling circuit is arranged to estimate the available capacity of the battery only when the detected temperature variation between the first battery percentage result and the second battery percentage result is lower than a specific threshold.

18. The power management apparatus of claim 12, wherein the controlling circuit is further arranged to determine a battery aging factor according to the estimated available capacity and an ideal capacity of the battery.

19. The power management apparatus of claim 12, wherein a slope of voltage changes within the specific operating range is greater than a slope of voltage changes within the normal operating range of the battery.

20. A power management apparatus capable of estimating/predicting an available capacity of a battery, comprising:
a storage circuit; and
a controlling circuit, coupled to the storage circuit, for loading program codes from the storage circuit to execute steps of:
measuring an internal resistance of the battery to generate a measured resistance; and
estimating the available capacity of the battery by referencing the measured resistance and a second look-up table defining a relation between the internal resistance of the battery and the available capacity of the battery.

21. The power management apparatus of claim 20, wherein the controlling circuit is further arranged to:
provide a first look-up table defining a relation between a battery cell voltage of the battery and the available capacity of the battery;
calculate levels of the battery cell voltage of the battery based on a minimum system current provided from the battery, a minimum system voltage, and values of the internal resistance; and
convert the first look-up table into the second look-up table by mapping the levels of the battery cell voltage of the battery to the values of the internal resistance of the battery.

22. The power management apparatus of claim 20, wherein the controlling circuit is further arranged to determine an aging factor according to the measured resistance and an ideal value of the internal resistance of the battery.
